(19) United States
(12) Patent Application Publication
(10) Pub. No.: US 2014/0176235 A1
(43) Pub. Date: Jun. 26, 2014

(54) Signal Absorption Circuit

(71) Applicant: David Robert Morgan, Addison, TX (US)

(72) Inventor: David Robert Morgan, Addison, TX (US)

(21) Appl. No.: 13/726,565

(22) Filed: Dec. 25, 2012

(51) Int. Cl. H03F 9/04

(52) U.S. Cl. CPC H03F 9/04
USPC 330/63

(57) ABSTRACT

This patent pertains to a new technique of maximizing the power transferred from a signal source. It accomplishes this by increasing the ratio of the electric to magnetic field and creating a high field impedance on the receiving end of the signal.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM

Not Applicable

### LISTING COMPACT DISC APPENDIX

Not Applicable

### BACKGROUND OF THE INVENTION

The invention is a type of signal amplifier that uses electromagnetic induction to boost the signal received from either an electromagnetic source or an acoustic source.

### BRIEF SUMMARY OF THE INVENTION

The invention routes a signal through the primary of a step up transformer while the flux within the transformer is increasing, and then routes the signal through the secondary in the opposing direction while the flux is decreasing. The potential energy in the form of magnetic flux is released at a voltage and current that differs from the voltage and current that generated the flux. Releasing this potential energy with a higher voltage creates a high “field impedance” that maximizes energy transfer.

### BRIEF DESCRIPTION OF THE SEVERAL VIEWS OF THE DRAWING

FIG. 1: This is the potential energy contained within the transformer as represented by the scalar value of the magnetic flux.

FIG. 1-1: A period of increasing potential energy.

FIG. 1-2: A period of decreasing potential energy.

FIG. 1-3: A period of increasing potential energy.

FIG. 1-4: A period of decreasing potential energy.

FIG. 2: A circuit that implements the principle for electromagnetic sources using transistors for the switches.

FIG. 2-1: Antenna used when targeting electromagnetic waves.

FIG. 2-2: Isolation transformer.

FIG. 2-3: Phase shifting coil of a suitable inductance to shift the phase of the input forward by pi/2 radians.

FIG. 2-4: Ground used when targeting electromagnetic waves.

FIG. 2-5: Transistor for allowing positive portion of the signal to flow to the secondary during the π/2 to π phase.

FIG. 2-6: Transistor for allowing negative portion of the signal to flow to the secondary during the 3 π/2 to 2 π phase.

FIG. 2-7: Transistor for allowing positive portion of the signal to flow to the primary during the 0 to π/2 phase.

FIG. 2-8: Transistor for allowing negative portion of the signal to flow to the primary during the π to 3 π/2 phase.

FIG. 2-9: Transistor for allowing positive output to flow from the primary during the π/2 to π phase.

FIG. 2-10: Transistor for allowing negative output to flow from the primary during the 3 π/2 to 2 π phase.

FIG. 2-11: Transistor for allowing positive output to flow from the secondary during the 0 to π/2 phase.

FIG. 2-12: Transistor for allowing negative output to flow from the secondary during the π to 3 π/2 phase.

FIG. 2-13: Transistor providing negative voltage during the π/2 to 3 π/2 portion of the signal.

FIG. 2-14: Transistor providing positive voltage during the 0 to π/2 and 3 π/2 to 2 π portions of the signal.

FIG. 2-15: Transistor providing negative voltage during the 0 to π/2 and 3 π/2 to 2 π portions of the signal.

FIG. 2-16: Transistor providing positive voltage during the π/2 to 3 π/2 portion of the signal.

FIG. 2-17: Transformer having two coils with differing inductances.

FIG. 2-18: Battery used to provide voltage to the switching transistors (i.e. the references 5 through 12).

FIG. 2-19: Output of the circuit.

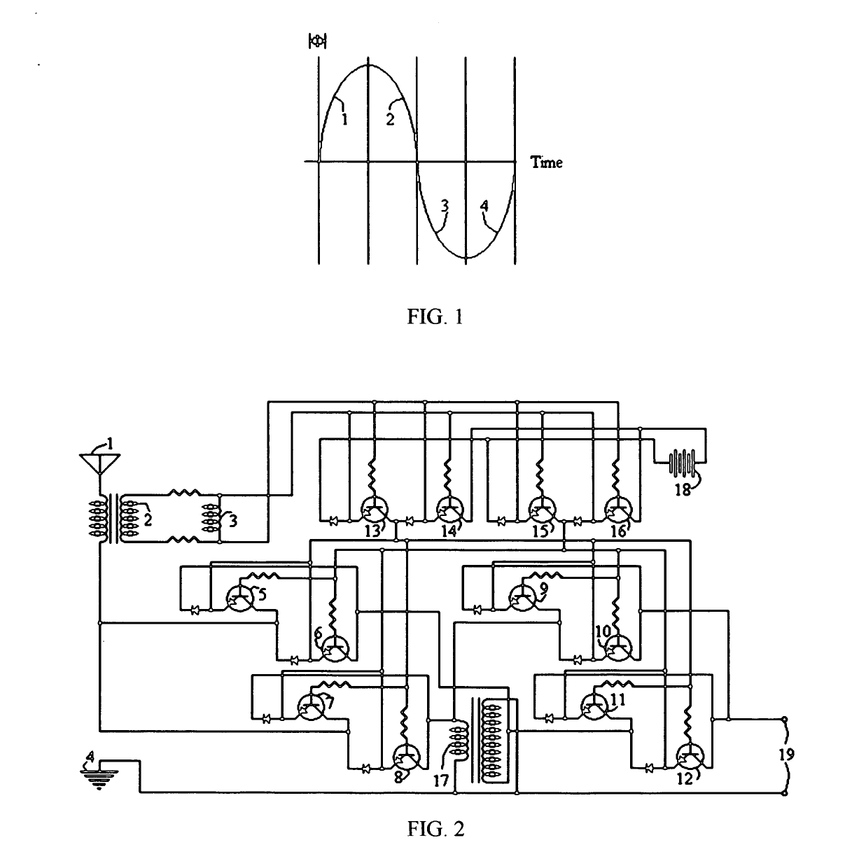

### DETAILED DESCRIPTION OF THE INVENTION

A signal that emanates from an electromagnetic source or an acoustic source is routed through the primary of a transformer building up flux in the core of the transformer. When the flux reaches its highest absolute magnitude, at π/2 radians, the signal is routed through the secondary in the opposing direction, such that current continues flowing in the direction it had been in the secondary. The flux that has been accumulated in the core begins to ebb as it does in the normal operation of a transformer, but the voltage and current of this phase are altered on the signal side of the transformer. This voltage and current correspond to the electric and magnetic fields being received by the antenna or an electro-acoustic bridge. By having a secondary that converts the flux to a higher voltage and lower amperage relative to that which generated the flux from the primary, the ratio of electric to magnetic field of this portion is skewed to be higher. This skewing of the ratio of electric to magnetic fields creates a higher field impedance, which maximizes power transfer from the signal source. When the flux and current reaches its minimum, at π radians, the signal is routed back to the primary again until flux reaches its maximum in the opposing direction, at which point it is routed to the secondary in the opposing direction, as it had been at the π/2 radians portion of the cycle.

The output of the transformer is routed from the secondary in the opposing direction during the portions of the cycle where flux is increasing, 0 to π/2 and π to 3 π/2, and from the primary during the portions of the cycle where flux is decreasing, π/2 to π and 3 π/2 to 2 π.

In the attached circuit, the design has been simplified by using a common ground between the primary and secondary. Note the ground on the secondary is on the side opposing from the primary.

The same connections of components can be used substituting triodes, tetrodes, or pentodes for the transistors. Krytrons may also be used.

An alternative design would be to use a relay or solid state relay. One DPDT relay could replace the eight transistors used to route the input and output to the primary and secondary.

Another possible alternative is to use thyristors to route the input and output.

The signal processing that drives the switches could use a capacitor for its phase shifting and invert the output. Also, an inverting integrator op-amp or a microcontroller could provide the signal processing functionality needed to run the switches.

1. A transformer having two coils (these coils henceforth referred to as the arbitrarily chosen primary and secondary) with the primary and the secondary having differing inductances, having switches that route a signal source (henceforth referred to as the signal) through the primary when the absolute current of the signal is increasing, and that subsequently, when the absolute current of the signal is decreasing, route the signal through the secondary in the opposing direction, such that the flux of the transformer maintains a consistent relative direction during the transition, having also the output of the device routed by switches from the secondary, also in the opposing direction, when the absolute current of the signal is increasing, and from the primary when the absolute current of the signal is decreasing.
